(19) United States
(12) Patent Application Publication
(10) Pub. No.: US 2018/0364572 A1
(43) Pub. Date: Dec. 20, 2018

(54) PHOTO-IMAGEABLE THIN FILMS WITH HIGH DIELECTRIC CONSTANTS

(71) Applicants: DOW GLOBAL TECHNOLOGIES LLC, Midland, MI (US); ROHM AND HAAS ELECTRONIC MATERIALS KOREA LTD., Cheonan, Chungcheongnam-do (KR); ROHM AND HAAS ELECTRONIC MATERIALS LLC, Marlborough, MA (US)

(72) Inventors: Caroline WOELFLE-GUPTA, Midland, MI (US); Yuanqiao RAO, Berwyn, PA (US); Seok HAN, Seoul (KR); Mitsuru HAGA, Minamikanbara-gun (JP); William H. H. WOODWARD, Harbor Beach, MI (US)

(21) Appl. No.: 15/781,726

(22) PCT Filed: Dec. 7, 2016
(86) PCT No.: PCT/US2016/065227

§ 371 Date: Jun. 6, 2018

Related U.S. Application Data
(60) Provisional application No. 62/268,540, filed on Dec. 17, 2015.

(51) Int. Cl. G03F 7/004; G03F 7/038

(52) U.S. Cl. CPC G03F 7/0047; G03F 7/038

(57) ABSTRACT

A formulation for preparing a photo-imageable film; said formulation comprising: (a) a negative photoresist comprising: (i) an acrylic binder having epoxy groups and (ii) a photo-active species; and (b) functionalized zirconium oxide nanoparticles.

### FIELD OF THE INVENTION

The present invention relates to a photo-imageable thin film with a high dielectric constant.

### BACKGROUND OF THE INVENTION

High dielectric constant thin films are of high interest for applications such as embedded capacitors, TFT passivation layers and gate dielectrics, in order to further miniaturize microelectronic components. One approach for obtaining a photo-imageable high dielectric constant thin film is to incorporate high dielectric constant nanoparticles in a photoresist. U.S. Pat. No. 7,630,043 discloses composite thin films based on a positive photoresist containing an acrylic polymer having alkali soluble units such as a carboxylic acid, and fine particles having a dielectric constant higher than 4 However, this reference does not disclose the binder used in the present invention.

### SUMMARY OF THE INVENTION

The present invention provides a formulation for preparing a photo-imageable film; said formulation comprising: (a) a negative photoresist comprising: (i) an acrylic binder having epoxy groups and (ii) a photo-active species; and (b) functionalized zirconium oxide nanoparticles.

### DETAILED DESCRIPTION OF THE INVENTION

Percentages are weight percentages (wt %) and temperatures are in ° C., unless specified otherwise. Operations were performed at room temperature (20-25° C.), unless specified otherwise. The term “nanoparticles” refers to particles having a diameter from 1 to 100 nm; i.e., at least 90% of the particles are in the indicated size range and the maximum peak height of the particle size distribution is within the range. Preferably, nanoparticles have an average diameter 75 nm or less; preferably 50 nm or less; preferably 25 nm or less; preferably 10 nm or less; preferably 7 nm or less. Preferably, the average diameter of the nanoparticles is 0.3 nm or more; preferably 1 nm or more. Particle sizes are determined by Dynamic Light Scattering (DLS). Preferably the breadth of the distribution of diameters of zirconia particles, as characterized by breadth parameter BP=(N75−N25), is 4 nm or less; preferably 3 nm or less; preferably 2 nm or less. Preferably the breadth of the distribution of diameters of zirconia particles, as characterized by BP=(N75−N25), is 0.01 or more. It is useful to consider the quotient W as follows:

W=(N75−N25)/Dm

where Dm is the number-average diameter. Preferably W is 1.0 or less; preferably 0.8 or less; preferably 0.6 or less; preferably 0.5 or less; preferably 0.4 or less. Preferably W is 0.05 or more.

Preferably, the functionalized nanoparticles comprise zirconium oxide and one or more ligands, preferably ligands which have alkyl, heteroalkyl (e.g., poly(ethylene oxide)) or aryl groups having polar functionality; preferably carboxylic acid, alcohol, trichlorosilane, trialkoxysilane or mixed chloro/alkoxy silanes; preferably carboxylic acid. It is believed that the polar functionality bonds to the surface of the nanoparticle. Preferably, ligands have from one to twenty-five non-hydrogen atoms, preferably one to twenty, preferably three to twelve. Preferably, ligands comprise carbon, hydrogen and additional elements selected from the group consisting of oxygen, sulfur, nitrogen and silicon. Preferably alkyl groups are from C1-C18, preferably C2-C12, preferably C3-C8. Preferably, aryl groups are from C6-C12. Alkyl or aryl groups may be further functionalized with isocyanate, mercapto, glycidoxy or (meth)acryloyloxy groups. Preferably, alkoxy groups are from C1-C4, preferably methyl or ethyl. Among organosilanes, some suitable compounds are alkyltrialkoxysilanes, alkoxy(polyalkyleneoxy)alkyltrialkoxysilanes, substituted-alkyltrialkoxysilanes, phenyltrialkoxysilanes, and mixtures thereof. For example, some suitable oranosilanes are n-propyltrimethoxysilane, n-propyltriethoxysilane, n-octyltrimethoxysilane, n-octyltriethoxysilane, phenyltrimethoxysilane, 2-[methoxy(polyethyleneoxy)propyll]trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanatopropyltriethoxysilane, 3-isocyanatopropyltrimethoxysilane, glycidoxypropyltrimethoxysilane, and mixtures thereof. Among organoalcohols, preferred are alcohols or mixtures of alcohols of the formula R10OH, where R10 is an aliphatic group, an aromatic-substituted alkyl group, an aromatic group, or an alkylalkoxy group. More preferred organoalcohols are ethanol, propanol, butanol, hexanol, heptanol, octanol, dodecyl alcohol, octadecanol, benzyl alcohol, phenol, oleyl alcohol, triethylene glycol monomethyl ether, and mixtures thereof. Among organocarboxylic acids, preferred are carboxylic acids of formula R11COOH, where R11 is an aliphatic group, an aromatic group, a polyalkoxy group, or a mixture thereof. Among organocarboxylic acids in which R11 is an aliphatic group, preferred aliphatic groups are methyl, propyl, octyl, oleyl, and mixtures thereof. Among organocarboxylic acids in which R11 is an aromatic group, the preferred aromatic group is C6H5. Preferably R11 is a polyalkoxy group. When R11 is a polyalkoxy group, R11 is a linear string of alkoxy units, where the alkyl group in each unit may be the same or different from the alkyl groups in other units. Among organocarboxylic acids in which R11 is a polyalkoxy group, preferred alkoxy units are methoxy, ethoxy, and combinations thereof. Functionalized nanoparticles are described, e.g., in US2013/0221279.

Preferably, the amount of functionalized nanoparticles in the formulation (calculated on a solids basis for the entire formulation) is from 50 to 95 wt %; preferably at least 60 wt %, preferably at least 70 wt %, preferably at least 80 wt %, preferably at least 90 wt %; preferably no greater than 90 wt %. “(Meth)acrylic” means acrylic or methacrylic. An “acrylic binder” is an aqueous emulsion of an acrylic polymer, which is a polymer having at least 60 wt % acrylic monomers, preferably at least 70 wt %, preferably at least 80 wt %, preferably at least 90 wt %. Acrylic monomers include (meth)acrylic acids and their C1-C22 alkyl or hydroxyalkyl esters; crotonic acid, itaconic acid, fumaric acid, maleic acid, maleic anhydride, (meth)acrylamides, (meth)acrylonitrile and alkyl or hydroxyalkyl esters of crotonic acid, itaconic acid, fumaric acid or maleic acid. The acrylic polymer may also comprise other polymerized monomer residues including, e.g., non-ionic (meth)acrylate esters, cationic monomers, monounsaturated dicarboxylates, vinyl esters of C1-C22 alkyl carboxylic acids, vinyl amides (including, e.g., N-vinylpyrrolidone), sulfonated acrylic monomers, vinyl sulfonic acid, vinyl halides, phosphorus-containing monomers, heterocyclic monomers, styrene and substituted styrenes.

Preferably, the negative photoresist comprises an oxime ester type photo-initiator, which upon UV exposure decomposes and generates a methyl radical which reacts with a multifunctional monomer present in the photoresist formulation to generate an insoluble network system.

Photo-reaction of an oxime ester type photo-initiator

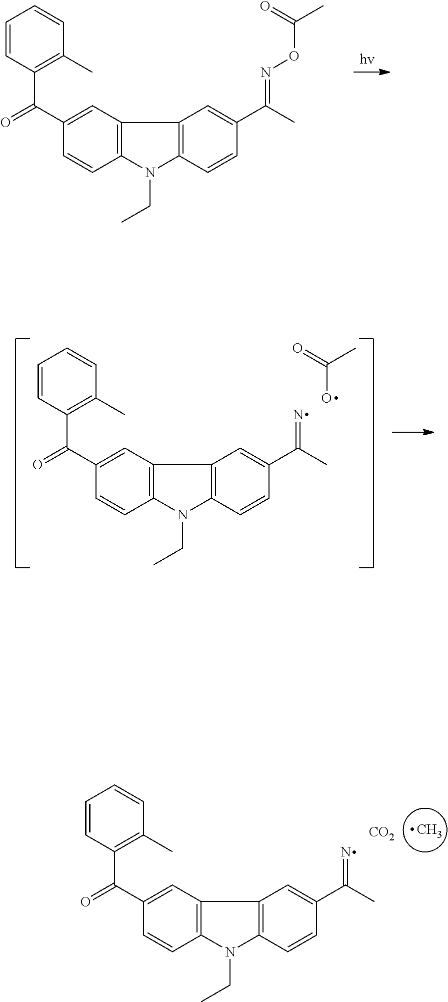

Example of multi-functional monomer (dipentaerythitol hexaacrylate)

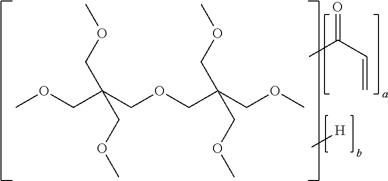

Preferably, the acrylic binder has weight average molecular weight (Mw) from 5,000 to 50,000 g/mole, preferably at least 7,000 g/mole, preferably at least 9,000 g/mole; preferably no greater than 25,000, preferably no greater than 18,000; all based on polystyrene equivalent molecular weight. Preferably, the acrylic binder comprises polymerized residues of: (i) a C₁-C₄ alkyl (meth)acrylate (preferably methyl), (ii) a C₃-C₁₂ (meth)acrylate ester comprising an epoxy group and (iii) a C₃-C₈ carboxylic acid monomer. Preferably, (meth)acrylates are methacrylates. Preferably, the epoxy groups are present in the second comonomer of the polyacrylate copolymer binder, which was produced via free radical polymerization. Examples of epoxy containing comonomers include 2,3-epoxypropylmethacrylate (glycidyl methacrylate), 4-hydroxybutyl acrylate glycidylether, or a cycloepoxy group containing (meth)acrylate. Preferably, the first (i) monomer content is from 52 to 63%, the second (ii) monomer content is from 18 to 22%, and the third (iii) monomer content is from 20 to 25%. Most specifically in the present examples, the first monomer content was 58%, the second monomer content was 20%, and the third monomer content was 22%.

Preferably, the film thickness is at least 50 nm, preferably at least 100 nm, preferably at least 500 nm, preferably at least 1000 nm; preferably no greater than 3000 nm, preferably no greater than 2000 nm, preferably no greater than 1500 nm. Preferably, the formulation is coated onto standard silicon wafers or Indium-Tin Oxide (ITO) coated glass slides

### Examples

### 1.1 Materials

Pixelligent PA (Pix-PA), and Pixelligent PB (Pix-PB) zirconium oxide (ZrO2) functionalized nanoparticles with a particle size distribution ranging from 2 to 13 nm were purchased from Pixelligent Inc. These nanoparticles were synthesized via solvo-thermal synthesis, with a zirconium alkoxide based precursor. The potential zirconium alkoxide based precursor used may include zirconium (IV) isopropoxide isopropanol, zirconium (IV) ethoxide, zirconium (IV) n-propoxide, and zirconium (IV) n-butoxide. Different potential capping agents described in the text of this invention can be added to the nanoparticles via a cap exchange process. The developer MF-26A (2.38 wt % tetramethyl ammonium hydroxoide) was provided by the Dow Electronic Materials group. The PNLK-0531 broadband g-line and i-line negative photoresist was provided by the Dow Electronics Materials group. The composition of PNLK-0531 is detailed in Table 1.

TABLE 1
Composition of the negative photoresist PNLK-0531.

| Component | Percentage |
|---|---|
| Polyacrylate copolymer | 14.2 |
| Photo initiator | 2.13 |
| Multi-functional monomer | 6.51 |
| Surfactant | 0.15 |
| Solvent | 77.01 |

### 1.2 Thin Film Preparation

Solutions were prepared containing different ratios of Pixelligent PA (Pix-PA) and Pixelligent PB (Pix-PB) type nanoparticles (both based on functionalized zirconium oxide nanoparticles) solutions mixed with the negative photoresist PNLK-0531. A spin curve was developed for each of the thin film compositions used, and spin speeds were adjusted accordingly to obtain target thin film thicknesses of 700 and 1000 nm for each composition.

### 1.3 Dielectric Constant Characterization

Four 50 nm thick gold electrodes 3 mm in diameter were deposited on each nanoparticle-photoresist thin films. The ITO was contacted with an alligator clip, and the gold electrodes with a gold wire to be able to apply a frequency sweep to the sample. The capacitance was measured for each sample, and the dielectric constant determined via Equation 1 with C being the capacitance, εr the dielectric constant, ε0 the vacuum dielectric permittivity, A the area of the electrode, and d the thickness of the film.

C=εrε0·A/d Equation 1

### 1.4 Photoimageability (Flood Exposure)

The PNLK-0531 based thin films on silicon wafers were subjected to a soft bake at 100° C. for 90 s, and dipped into a petri dish containing MF-26A for 80 s.

### 1.5 Photo-Patternability

Process conditions used for generating contrast curves for the negative photoresist PNLK-0531, and the nanoparticle-PNLK-0531 composite thin films are detailed in Table 2. Process conditions used for generating trench patterns are summarized in Table 3. Process conditions for generating contact hole patterns are summarized in Table 4.

TABLE 2
Process conditions used for generating the contrast
curve for the thin films based on PNLK-0531.

| | |
|---|---|
| Substrate | Si |
| Film thickness | 1.0 μm after soft bake |
| Soft bake | 100° C. for 120 s |
| Exposure step | 20-100 mJ/cm² @ 365 nm |
| Developer step | 2.38 wt % TMAH, 70 s |
| Hard Bake | 230° C., 30 min in convection oven |

TABLE 3
Process conditions used for generating trench patterns
of the PNLK-0531 based thin films.

| | |
|---|---|
| Substrate | Si |
| Film thickness | 1.0 μm after soft bake |
| Soft bake | 100° C. for 120 s |
| Exposure step | 100 mJ/cm² @ 365 nm |
| Developer step | 2.38 wt % TMAH, 70 s |
| Mask gap | 50 μm tape gap |
| Hard bake | 230° C., 30 min in convection oven |

TABLE 4
Process conditions used for generating contact hole
patterns of the PNLK-0531 based thin films.

| | |
|---|---|
| Substrate | Si |
| Film thickness | 1.0 μm after soft bake |
| Soft bake | 100° C. for 120 s |
| Exposure step | 100 mJ/cm² @ 365 nm |
| Developer step | 2.38 wt % TMAH, 70 s |
| Mask gap | 50 μm tape gap |
| Hard bake | 230° C., 30 min in convection oven |

### 1.6 Nanoparticle Dispersion in the Film

Nanoparticle-photoresist thin film samples spin-coated on Kapton substrates approximately 2.5 cm2 each were used. A 1 mm×2 mm piece of film was extracted from the corner of the spin-coated films with a razor blade. This piece was mounted in a chuck so that the thickening of the layer (the drip at the corner) could be sectioned into without having to include the Kapton substrate. A Leica UC6 ultramicrotome was operated at room temperature. The sectioning thickness was set to 45 nm at a cutting rate of 0.6 cuts/s. A diamond wet knife was used for all sectioning. Sections were floated on a water surface and collected onto 150 mesh formvar-coated copper grids and dried in the open atmosphere at ambient temperature. A JEOL transmission electron microscope was operated at 100 kV of accelerating voltage with a spot size of 3. Both the condenser and objective apertures were set to large. The microscope was controlled by Gatan Digital Micrograph v3.10 software. Image data was collected using a Gatan Multiscan 794 CCD camera. Adobe Photoshop v9.0 was used to post-process all images.

### 1.7 Thin Films Thickness Measurements

The coatings on the glass slides were scratched to expose the glass surface for measuring the coating thicknesses. To verify the accuracy of the measurements and ensure that the glass substrate was not damaged by the stylus, the scratching was also done on the glass without coating, and it was observed that no damage was created when a similar force was applied. The surface profile was obtained on a Dektak 150 stylus profilometer. The thickness was measured as the height between surface and the flat bottom of the scratch. For each sample at least 8 measurements were done at 2 different scratches.

### 2. Results

### 2.1 Dielectric Constant Results

Table 5 lists the permittivities measured at 1.15 MHz of several thin films made of different amounts of Pixelligent PA (Pix-PA) and Pixelligent PB (Pix-PB) nanoparticles mixed with the PNLK-0531 negative photoresist, as a function of weight percent of nanoparticles incorporated in the photoresist. The permittivity obtained was as high as 11.99 for the thin films based on the Pix-PA type nanoparticles and 89.33 wt % of nanoparticles present in the corresponding thin film, while it was as high as 11.93 for the thin films based on the Pix-PB type nanoparticles and 93.46 wt % of nanoparticles present in the corresponding thin film. The permittivity was still higher than the Dow customer CTQ of 6.5 for the Pix-PA based thin films, and a corresponding wt % of 59.80, as well as for the Pix-PB based thin films, and a corresponding wt % of 68.50. Table 6 shows the same trends for thin films of Pix-PA and PNLK-0531, and a target thickness of 700 nm.

TABLE 5
Permittivity measured at 1.15 MHz of PNLK-0531-nanoparticle thin films, as a function of the weight
percent of nanoparticles incorporated in the photoresist and a target film thickness of 1000 nm.

| | | | | Wt % of | Film | | Standard |
|---|---|---|---|---|---|---|---|
| Sample | Pix-PA | Pix-PB | PNLK-0531 | nanoparticles | Thickness (nm) | Permittivity | deviation |
| Pix-nt-1 | 2.0028 | | 0.2662 | 94.31 | 850 | 11.14 | 0.23 |
| Pix-nt-2 | 2.0014 | | 0.5047 | 83.33 | 763.50 | 11.99 | 0.88 |
| Pix-nt-3 | 2.0016 | | 1.0087 | 80.83 | 787.25 | 9.79 | 0.24 |
| Pix-nt-4 | 2.0028 | | 2.0041 | 71.37 | 730.00 | 6.80 | 0.54 |
| Pix-nt-5 | 2.0015 | | 3.0004 | 59.80 | 867.75 | 6.67 | 0.23 |
| Pix-nt-6 | 2.0026 | | 6.0023 | 43.00 | 867.00 | 4.97 | 0.13 |
| Pix-nt-7 | | 2.0021 | 0.2823 | 93.46 | 720.75 | 11.93 | 1.01 |
| Pix-nt-9 | | 2.0007 | 1.0144 | NA | 651.25 | 8.09 | 1.91 |
| Pix-nt-10 | | 2.0000 | 2.0011 | 68.50 | 800.25 | 7.54 | 0.90 |
| Pix-nt-11 | | 2.0023 | 3.0004 | 60.09 | 906.50 | 6.38 | 0.26 |
| Pix-nt-12 | | 2.0015 | 6.0006 | 42.27 | 933.75 | 5.06 | 0.21 |
| PNLK-0531 | | NA | NA | 0.00 | 927.33 | 3.76 | 0.33 |

TABLE 6
Permittivity measured at 1.15 MHz of PNLK-0531-nanoparticle thin
films, as a function of the weight percent of nanoparticles incorporated
in the photoresist and a target film thickness of 700 nm.

| | | | Wt % of | Film | | Standard |
|---|---|---|---|---|---|---|
| Sample | Pix-PA | PNLK-0531 | nanoparticles | thickness (nm) | Permittivity | deviation |
| Pix-nt-1-1 | 2.0028 | 0.2662 | 94.31 | 660.25 | 11.52 | 1.25 |
| Pix-nt-2-1 | 2.0014 | 0.5047 | 89.33 | 639.50 | 11.91 | 0.22 |
| Pix-nt-3-1 | 2.0016 | 1.0087 | 80.83 | 616.50 | 10.07 | 0.46 |
| Pix-nt-4-1 | 2.0028 | 2.0041 | 71.37 | 627.50 | 7.16 | NA |
| Pix-nt-5-1 | 2.0015 | 3.0004 | 59.80 | 617.50 | 5.87 | 0.40 |
| Pix-nt-6-1 | 2.0026 | 6.0023 | 43.00 | 622.75 | 7.34 | 0.97 |
| PNLK-0531 | NA | NA | NA | 645.33 | 3.95 | 1.59 |

### 2.2 Photoimageability of the Composite Thin Films

Table 7 and 8 show the thicknesses of the PNLK-0531 based thin films before and after experiencing a soft bake at 100° C. for 90 s, and a 80 s dip in MF-26A (2.38 wt % TMAH). All the thin films were removed after 80 s in the developer, independently of the type of nanoparticle used (Pix-PA or Pix-PB) and the wt % of nanoparticles present in the thin films

TABLE 7
Thickness of the PNLK-0531-nanoparticle thin films before
and after experiencing developing conditions for an
initial target film thickness of 700 nm.

| | | Initial thickness | Thickness after 80 s in |
|---|---|---|---|
| Sample | Soft bake | (nm) | MF-26A (nm) |
| Pix-nt-1-1 | 100° C. for 90 s | 639.22 | 3.02 |
| Pix-nt-2-1 | 100° C. for 90 s | 624.96 | 4.35 |
| Pix-nt-3-1 | 100° C. for 90 s | 606.37 | 4.92 |
| Pix-nt-4-1 | 100° C. for 90 s | 607.43 | 5.24 |
| Pix-nt-5-1 | 100° C. for 90 s | 599.91 | 5.74 |
| Pix-nt-6-1 | 100° C. for 90 s | 612.60 | 3.75 |
| Pix-nt-10-1 | 100° C. for 90 s | 606.73 | 2.81 |
| Pix-nt-11-1 | 100° C. for 90 s | 615.35 | 2.67 |
| Pix-nt-12-1 | 100° C. for 90 s | 672.60 | 2.53 |

TABLE 8
Thickness of the PNLK-0531 nanoparticle thin films before
and after experiencing developing conditions for an
initial target film thickness of 1000 nm.

| | | | Thickness after 80 s in |
|---|---|---|---|
| Sample | Soft bake | Thickness (nm) | MP-26A (nm) |
| Pix-nt-1 | 100° C. for 90 s | 879.14 | 1.94 |
| Pix-nt-2 | 100° C. for 90 s | 834.98 | 2.65 |
| Pix-nt-3 | 100° C. for 90 s | 854.96 | 2.13 |
| Pix-nt-4 | 100° C. for 90 s | 838.76 | 2.51 |
| Pix-nt-5 | 100° C. for 90 s | 915.51 | 1.97 |
| Pix-nt-6 | 100° C. for 90 s | 910.05 | 2.12 |
| Pix-nt-7 | 100° C. for 90 s | 802.84 | 2.94 |
| Pix-nt-9 | 100° C. for 90 s | 736.73 | 3.03 |
| Pix-nt-10 | 100° C. for 90 s | 832.31 | 2.84 |
| Pix-nt-11 | 100° C. for 90 s | 920.79 | 2.61 |
| Pix-nt-12 | 100° C. for 90 s | 1026.30 | 2.69 |

### 2.3 Photo-Patternability

### 2.3.1 Contrast Curve

As shown in Table 9, PNLK-0531 containing 50-70 wt % of Pix-PA gave reasonable film retention (between 60 and 66% for an exposure energy of 20 mJ/cm2, and between 70 and 80% for an exposure energy equal or above 40 mJ/cm2, and the processing conditions described in Table 2). No develop residue could be noticed on the bulk area

TABLE 9
Contrast curve.

| | Normalized Film Retention (%) | | |
|---|---|---|---|
| | 50% Pix- | 60% Pix- | 70% Pix- |
| Exposure Energy | PA/50% | PA/40% | PA/30% |
| (mJ/cm²) | PNLK-0531 | PNLK-0531 | PNLK-0531 |
| 100.00 | 77.77 | 77.22 | 76.05 |
| 90.00 | 77.83 | 77.19 | 75.71 |
| 85.00 | 77.41 | 76.81 | 75.04 |
| 80.00 | 77.20 | 76.79 | 74.73 |
| 75.00 | 76.88 | 76.65 | 74.25 |
| 70.00 | 77.00 | 76.50 | 74.18 |
| 65.00 | 76.63 | 76.58 | 73.93 |
| 60.00 | 76.46 | 76.54 | 73.72 |
| 55.00 | 76.04 | 76.46 | 73.57 |
| 50.00 | 75.59 | 74.87 | 73.14 |
| 45.00 | 75.41 | 74.63 | 72.67 |
| 40.00 | 74.57 | 74.16 | 71.71 |
| 35.00 | 73.88 | 73.29 | 70.10 |
| 30.00 | 72.74 | 72.58 | 67.41 |
| 25.00 | 68.03 | 66.73 | 64.28 |
| 20.00 | 65.86 | 64.85 | 61.63 |
| 15.00 | 63.21 | 62.20 | 54.54 |
| 10.00 | 53.02 | 46.72 | 43.95 |
| 0.00 | 0.00 | 0.00 | 0.53 |

### 2.3.2 Dense Trenches

As shown in Table 10, well-defined 1:1 9-10 μm dense trenches could be obtained for PNLK-0531 thin films (for a thickness around 650 nm) containing 50 wt % of Pix-PA at 20 mJ/cm² exposure energy. Well-defined 1:1 8 μm dense trenches could be obtained as well for PNLK-0531 thin films containing 60 wt % of Pix-PA at the same exposure energy. These films gave a permittivity of 6.8, which is higher than the Dow customer CTQ of 6.5. Corresponding film thicknesses are given in Table 11.

TABLE 10
Dense trenches.

| | Solid ratio of | | Exposure energy | | |
|---|---|---|---|---|---|
| | NP:NPL (wt %) | | (mJ/cm²) | | |
| Sample | Pix-PA | PNLK-0531 | 20 | 40 | 60 |
| PNLK-0531 | 0 | 100 | 10 μm | 15 μm | 20 μm |
| MH536869-74-1 | 50 | 50 | 9-10 μm | 15 μm | 15 μm |
| ε = 5.4 | | | | | |
| MH536869-74-1 | 60 | 40 | 8 μm | 15 μm | 15 μm |
| ε = 6.8 | | | | | |

TABLE 11
Film thicknesses

| | Solid ratio of | | Exposure energy | | |
|---|---|---|---|---|---|
| | NP:NPL(wt %) | | (mJ/cm²) | | |
| Sample | Pix-PA | PNLK-0531 | 20 | 40 | 60 |
| PNLK-0531 | 0 | 100 | 777 nm | 844 nm | 872 nm |
| MH536869-74-1 | 50 | 50 | 661 nm | 747 nm | 764 nm |
| ε = 5.4 | | | | | |
| MH536869-74-1 | 60 | 40 | 652 nm | 746 nm | 767 nm |
| ε = 6.8 | | | | | |

### 2.3.3 Contact Holes

As shown in Tables 12 the contact hole patterns were reasonably well defined for the control PNLK-0531, and the thin films containing 50 wt % of Pix-PA nanoparticles, and presenting a permittivity of 5.4 for an exposure energy between 10 and 15 mJ/cm2. The contact hole pattern was reasonably well defined too for the thin film containing 60 wt % of Pix-PA nanoparticles, and presenting a permittivity of 6.8 for an exposure energy of 15 mJ/cm2. Finally, for an exposure energy of 20 mJ/cm2, the contact hole pattern was reasonably well defined for the thin film containing 70 wt % of Pix-PA nanoparticles, and presenting a permittivity of 8.1. Corresponding film thicknesses are given in Table 13.

TABLE 12
Contact hole patterns.

| | Solid ratio of | | Exposure energy | | |
|---|---|---|---|---|---|
| | NP:NPL (wt %) | | (mJ/cm²) | | |
| Sample | Pix-PA | PNLK-0531 | 10 | 15 | 20 |
| PNLK-0531 | 0 | 100 | Defined | Defined | Not well |
| | | | pattern | pattern | defined |
| | | | | | pattern |
| MH536869- | 50 | 50 | Defined | Defined | Not well |
| 74-1 ε = 5.4 | | | pattern | pattern | defined |
| | | | | | pattern |
| MH536869- | 60 | 40 | Peeled | Defined | Not well |
| 74-1 ε = 6.8 | | | | pattern | defined |
| | | | | | pattern |
| MH536869- | 70 | 30 | Peeled | Peeled | Defined |
| 74-3 ε = 8.1 | | | | | pattern |

TABLE 13
Film thicknesses.

| | Solid ratio of | | Exposure energy | | |
|---|---|---|---|---|---|
| | NP:NPL (wt %) | | (mJ/cm²) | | |
| Sample | Pix-PA | PNLK-0531 | 10 | 15 | 20 |
| PNLK-0531 | 0 | 100 | 640 nm | 719 nm | 777 nm |
| MH536869-74-1 | 50 | 50 | 532 nm | 634 nm | 661 nm |
| ε = 5.4 | | | | | |
| MH536869-74-1 | 60 | 40 | 469 nm | 625 nm | 652 nm |
| ε = 6.8 | | | | | |
| MH536869-74-3 | 70 | 30 | 443 nm | 550 nm | 622 nm |
| ε = 8.1 | | | | | |

### 2.4 Transmittance

Photomicrographs of the dispersion of ZrO₂ functionalized nanoparticles in a negative photoresist PNLK-0531 thin film containing 59.8 wt % of nanoparticles showed that the nanoparticles were very well dispersed in the photoresist, with no signs of nanoparticle agglomeration present Transmittance of a PNLK-0531 thin film containing 59.8 wt % of Pix-PA nanoparticles was approximately 97% at 400 nm, which is higher than the 90% CTQ required by the customers. Transmittance was above 95% throughout the visible region.

1. A formulation for preparing a photo-imageable film; said formulation comprising: (a) a negative photoresist comprising: (i) an acrylic binder having epoxy groups and (ii) a photo-active species; and (b) functionalized zirconium oxide nanoparticles.

2. The formulation of claim 1 in which the functionalized zirconium oxide nanoparticles have an average diameter from 0.3 nm to 50 nm.

3. The formulation of claim 2 in which the functionalized zirconium oxide nanoparticles comprise ligands which have carboxylic acid, alcohol, trichlorosilane, trialkoxysilane or mixed chloro/alkoxy silane functionality.

4. The formulation of claim 3 in which the ligands have from one to twenty non-hydrogen atoms.

5. The formulation of claim 4 in which the acrylic binder comprises polymerized residues of: (i) a C1-C4 alkyl (meth)acrylate, (ii) a C3-C12 (meth)acrylate ester comprising an epoxy group and (iii) a C3-C8 carboxylic acid monomer.

6. The formulation of claim 5 in which the amount of functionalized nanoparticles in the formulation, calculated on a solids basis for the entire formulation, is from 50 to 95 wt %.

7. The formulation of claim 6 in which the acrylic binder has weight average molecular weight from 5,000 to 50,000.
